(19) United States
(12) Patent Application Publication
(10) Pub. No.: US 2025/0070096 A1
(43) Pub. Date: Feb. 27, 2025

(54) SIDE LIGHT-EMITTING DISPLAY DEVICE

(71) Applicant: HYUNDAI MOBIS CO., LTD., Seoul (KR)

(72) Inventor: Sung Min YOO, Yongin-si (KR)

(73) Assignee: HYUNDAI MOBIS CO., LTD., Seoul (KR)

(21) Appl. No.: 18/647,101

(22) Filed: Apr. 26, 2024

(30) Foreign Application Priority Data
Aug. 21, 2023 (KR) 10-2023-0109215

(51) Int. Cl. H01L 25/075; H01L 33/60; H01L 33/64

(52) U.S. Cl. CPC H01L 25/0753; H01L 33/60; H01L 33/641; H01L 33/642; H01L 33/644

(57) ABSTRACT

A side light-emitting display device includes a case, a front display panel configured to display an image to the front of the case and one or more side light sources disposed to be spaced apart from the front display panel and configured to emit light to a side surface of the case.

### CROSS-REFERENCE TO RELATED APPLICATIONS

This application claims priority from and the benefit of Korean Patent Application No. 10-2023-0109215, filed on Aug. 21, 2023, which is hereby incorporated by reference for all purposes as if set forth herein.

### TECHNICAL FIELD

Exemplary embodiments of the present disclosure relate to a side light-emitting display device, and more particularly, to a side light-emitting display device that emits light through a side thereof in addition to a front thereof.

### BACKGROUND

Modern people perform work, search for information, or watch image content in a boarding space even while getting on means of transportation, for example, a vehicle, a train, a passenger plane, or a passenger ship in order to travel due to busy life patterns.

In order to keep step with such a life pattern, a display device may be installed in a boarding space of means of transportation. For example, the display device may be installed on a rear surface of the back of a front seat in a vehicle, a train, or a passenger plane.

However, the existing display device that is installed in the boarding space of the means of transportation has problems in that it has a small screen and a surrounding image not related to an image that is displayed on a screen appears on the screen. Due to the problems, concentration and a feeling of immersion of a passenger who views the display device may be reduced, work efficiency may be reduced when the passenger performs a work, and the passenger may not have a comfortable time within the means of transportation.

An existing display device such as discussed in the above background was disclosed in Korean Patent No. 10-0792899 (Jan. 2, 2008 entitled “Display unit for vehicle with Rear Seat Entertainment System.”)

### SUMMARY

Various embodiments disclosed herein are directed to providing a side light-emitting display device that emits light through a side surface thereof in order to improve concentration and a feeling of immersion of a viewer.

In an embodiment, a side light-emitting display device includes a case, a front display panel configured to display an image to the front of the case and one or more side light sources disposed to be spaced apart from the front display panel and configured to emit light to a side surface of the case.

Each of the side light sources may include a plurality of color LED packages that emit light having a plurality of colors.

The plurality of color LED packages may be arranged along the side surface of the case within the case.

The case may include a light diffusion plate configured to enable the light projected from the side light source to be projected from the side surface of the case to the outside while diffusing the light.

The case may include a frame disposed behind the front display panel and a rear cover disposed behind the frame. A case-internal space in which the side light source is disposed may be formed between the frame and the rear cover.

A gap from which the light projected from the side light source is emitted may be formed between an outer edge of the frame and an outer edge of the rear cover.

A side light source circuit board on which the side light source is mounted and a heat dissipation panel configured to support the side light source circuit board may be disposed in the case-internal space.

The heat dissipation panel may include a light blocking rib configured to block the light projected from the side light source so that the light does not proceed in a direction opposite a direction toward the gap.

The side light-emitting display device may further include boss portions configured to fixe and support the front display panel and to extend toward the heat dissipation panel through the frame.

The heat dissipation panel and the boss portions may be fastened by fastening screws.

The heat dissipation panel may be formed of a metal material including aluminum.

The side light-emitting display device may further include a light reflector installed in the case-internal space and configured to reflect the light that is projected from the side light source and proceeds in a direction that becomes distant from the gap so that the light proceeds toward the gap.

For example, when a passenger who uses means of transportation, such as a vehicle or an airplane, watches image content by using the side light-emitting display device according to an embodiment of the present disclosure, the passenger may have an effect in that a screen looks bigger, and a visual stimulus, such as a surrounding image that hinders the immersion of the image content, may not appear on the screen.

Accordingly, concentration and a feeling of immersion of the passenger who views the side light-emitting display device are improved. Accordingly, work efficiency can be improved if the passenger performs a work, and the passenger can have an interesting and comfortable leisure time if the passenger enjoys leisure within the means of transportation.

Furthermore, if a user of the side light-emitting display device according to an embodiment of the present disclosure turns on only the side light source without turning on the front display panel, the user can have a sense of psychological stability and take a calm rest because the side light source may function as indirect lighting or major lighting.

### BRIEF DESCRIPTION OF THE DRAWINGS

FIG. 1 is a perspective view of a side light-emitting display device according to a first embodiment of the present disclosure.

FIG. 2 is a cross-sectional view taken along line II-II in FIG. 1.

FIG. 3 is a cross-sectional view of a side light-emitting display device according to a second embodiment of the present disclosure.

FIG. 4 is a flowchart illustrating an example of a method of using the side light-emitting display device according to an embodiment of the present disclosure.

FIG. 5 is a front view illustrating the state in which the side light-emitting display device of FIGS. 1 to 3 has been installed within a vehicle.

### DETAILED DESCRIPTION

Hereinafter, a side light-emitting display device according to embodiments of the present disclosure will be described with reference to the accompanying drawings. Terminologies that are used in this specification are terminologies that are used to properly represent embodiments of the present disclosure. The terminologies may be changed depending on a user or operator's intention or practice of the field to which the present disclosure pertains. Accordingly, such terminologies should be defined based on the overall contents of this specification.

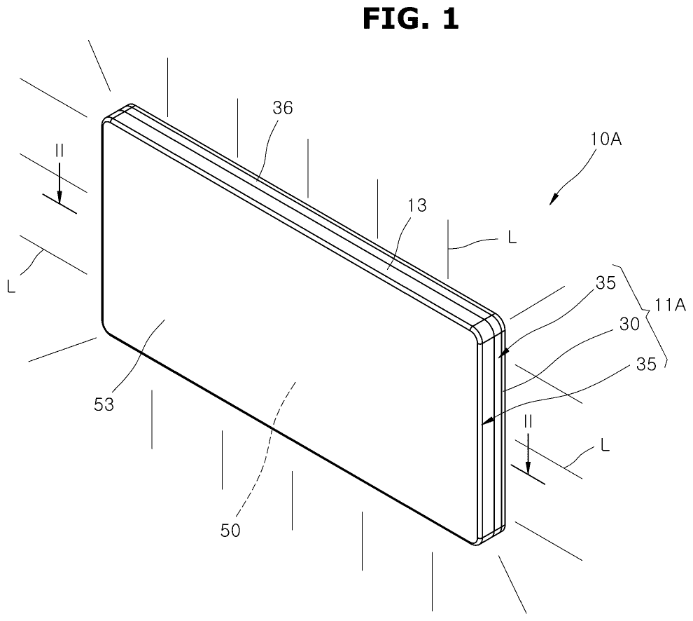

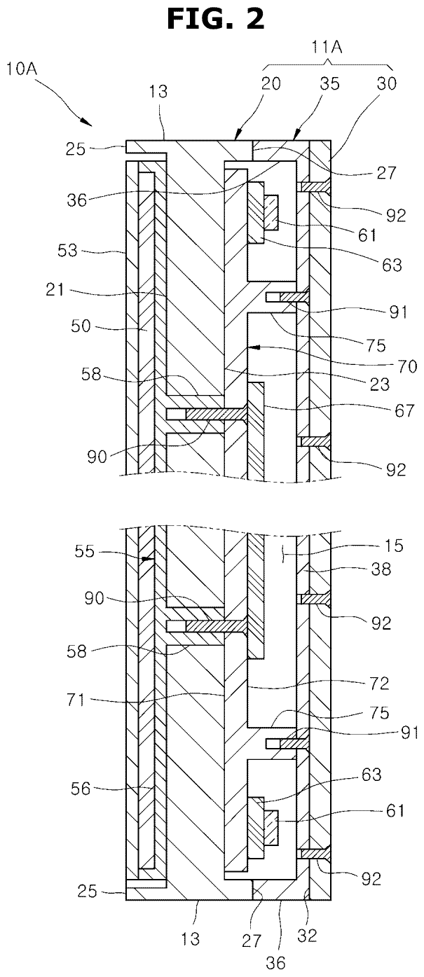

FIG. 1 is a perspective view of a side light-emitting display device according to a first embodiment of the present disclosure. FIG. 2 is a cross-sectional view taken along line II-II in FIG. 1. Referring to FIGS. 1 and 2, a side light-emitting display device 10A according to the first embodiment of the present disclosure includes a case 11A, a front display panel 50, and a side light source.

The front display panel 50 displays an image, such as a still image or a moving image, to the front of the case 11A. The front display panel 50 may include a backlight unit (BLU), a liquid crystal panel in front of the BLU, and an LCD panel including a front polarization sheet and a rear polarization sheet on a front surface and rear surface of the liquid crystal panel, respectively, for example. However, the LCD panel is merely an example of the front display panel 50, and may be substituted with a different type of front display panel, for example, an OLED panel.

The front display panel 50 may further include a touch panel or a touch sheet that is disposed in front of the LCD panel or the OLED panel so that indication by a user's touch is input to the front display panel.

The case 11A may include a frame 20, a rear cover 30, and a light diffusion plate light diffuser 35. The frame 20 may be disposed behind the front display panel 50. The frame 20 may include a front part 21 toward the front display panel 50, a rear part 23 on the side opposite the front part 21, a front end edge part 25 that more protrudes from an outer circumference part of the front part 21 to the front thereof than the front part 21, and a rear end edge part 27 that more protrudes from an outer circumference part of the rear part 23 to the back thereof than the rear part 23.

The rear cover 30 may be disposed behind the frame 20. A case-internal space 15 in which a side light source may be formed between the frame 20 and the rear cover 30. A gap 32 from which light L that is projected from the side light source is emitted may be formed between an outer edge of the frame 20, in other words, the rear end edge part 27 and an outer edge of the rear cover 30.

The frame 20 and the rear cover 30 may each be formed of synthetic resin or a metal material, for example. If the frame 20 and the rear cover 30 are formed of synthetic resin, the frame 20 may be manufactured by injection molding. If the frame 20 and the rear cover 30 are formed of metal materials, the frame 20 may be formed by machine processing, such as die casting, forging, or press working.

The side light source emits the light L to a side surface 13 of the case 11A. Specifically, the light L that is projected from the side light source may be emitted in a direction that intersects the side surface 13 of the case 11A through the gap 32 between the frame 20 and the rear cover 30. The side light source is disposed to be spaced apart from the front display panel 50.

The side light source may include a plurality of color LED packages 61 that emit the light L having a plurality of colors. The plurality of color LED packages 61 may be arranged within the case 11A, specifically, along the side surface 13 of the case 11A in the case-internal space 15.

Each of the color LED packages 61 has been packaged so that a plurality of LEDs that emit the light L having different colors becomes one element. Each of the color LED packages 61 may be constructed to emit all natural colors by packaging one LED R that emits red (R) light, one LED G that emits green (G) light, and one LED B that emits blue (B) light, for example.

The side light-emitting display device 10A may further include a side light source circuit board 63, a main circuit board 67, a heat dissipation panel 70, an internal housing 55, and protection glass 53. The side light source, in other words, the plurality of color LED packages 61 may be mounted on the side light source circuit board 63. Circuits for supplying power to the plurality of color LED packages 61 may be formed in the side light source circuit boards 63, respectively.

The side light source circuit boards 63 may extend in the direction in which the plurality of color LED packages 61 has been arranged. Specifically, the side light source circuit boards 63 may extend in a direction in which an edge of the front display panel 50 extends.

The main circuit board 67 may be disposed in a middle area of the case-internal space 15, which is surrounded by the side light source circuit boards 63. A front display panel control circuit that controls the front display panel 50 to receive image data from the outside and to display an image corresponding to the image data may be formed in the main circuit board 67. Furthermore, a side light source control circuit that controls the flickering (ON/OFF) of the side light source, that is, the plurality of color LED packages 61, may be formed in the main circuit board 67.

The heat dissipation panel 70 may discharge heat from the side light source circuit boards 63 and the main circuit board 67 by coming into contact with and supporting the side light source circuit boards 63 and the main circuit board 67. The heat dissipation panel 70 may be supported against the rear part 23 of the frame 20. For proper heat dissipation performance, the securing of strength, and a cost reduction, the heat dissipation panel 70 may be formed of a metal material including aluminum, for example, an aluminum alloy or pure aluminum.

The internal housing 55 may include a display panel seating plate part 56 and a plurality of boss portions 58. The display panel seating plate part 56 is an approximately plate-shaped portion that fixes and supports the front display panel 50, and may be seated on the front part 21 of the frame 20.

The plurality of boss portions 58 may protrude and extend from a rear surface of the display panel seating plate part 56 to the back thereof. The plurality of boss portions 58 may extend toward the heat dissipation panel 70 through the frame 20. The heat dissipation panel 70 and the plurality of boss portions 58 may be mutually coupled and fixed by a plurality of fastening screws 90.

When the plurality of fastening screws 90 is fastened, the display panel seating plate part 56 may be closely attached to the front part 21 of the frame 20, and the heat dissipation panel 70 may be closely attached to the rear part 23 of the frame 20.

The protection glass 53 is a transparent glass plate that protects a front surface of the front display panel 50 by covering the front surface, and may be attached to the front display panel 50. The protection glass 53 may be supported by an edge of an outer circumference of the display panel seating plate part 56.

The heat dissipation panel 70 may include light blocking ribs 75 that block the light L projected from the plurality of color LED packages 61, that is, the side light source, so that the light does not proceed in a direction opposite a direction toward the gap 32, that is, a central part of the heat dissipation panel 70.

The light blocking rib 75 may protrude in a direction toward the rear cover 30, that is, to the back thereof. Like the side light source circuit boards 63, the light blocking ribs 75 may extend in the direction in which the plurality of color LED packages 61 has been arranged. The side light source may be disposed between the light blocking rib 75 and the gap 32 close to the light blocking rib 75.

The overheating of the main circuit board 67 can be prevented because the light blocking rib 75 blocks the light L that is directed toward a central part of the case-internal space 15 without being directed toward the gap 32. Furthermore, if the heat dissipation panel 70 is formed of a metal material capable of reflecting light, brightness of the light L that is emitted through the gap 32 can be improved because the light L reflected by the light blocking rib 75 can be emitted to the side surface 13 of the case 11A through the gap 32.

The light diffusion plate 35 included in the case 11A enables the light L projected from the side light source, that is, the plurality of color LED packages 61, to be projected from the side surface of the case 11A to the outside while diffusing the light. The light diffusion plate 35 may include a gap closing part 36 that closes the gap 32 of the side surface 13 of the case 11A and a flat reinforcement part 38 that comes into contact with a front surface of the rear cover 30. The gap closing part 36 and the reinforcement part 38 may be connected to form an angle at which the gap closing part 36 and the reinforcement part 38 are approximately almost perpendicular to each other.

A so-called hotspot phenomenon does not occur or can be reduced in the light L that is emitted from the side surface 13 of the case 11A because the light diffusion plate 35 diffuses the light L that is projected from the color LED packages 61 and then passes through the gap 32.

The reinforcement part 38 and the light blocking ribs 75 may be mutually coupled and fixed by fastening screws 91. The rear cover 30 and the reinforcement part 38 may be mutually coupled and fixed by fastening screws 92.

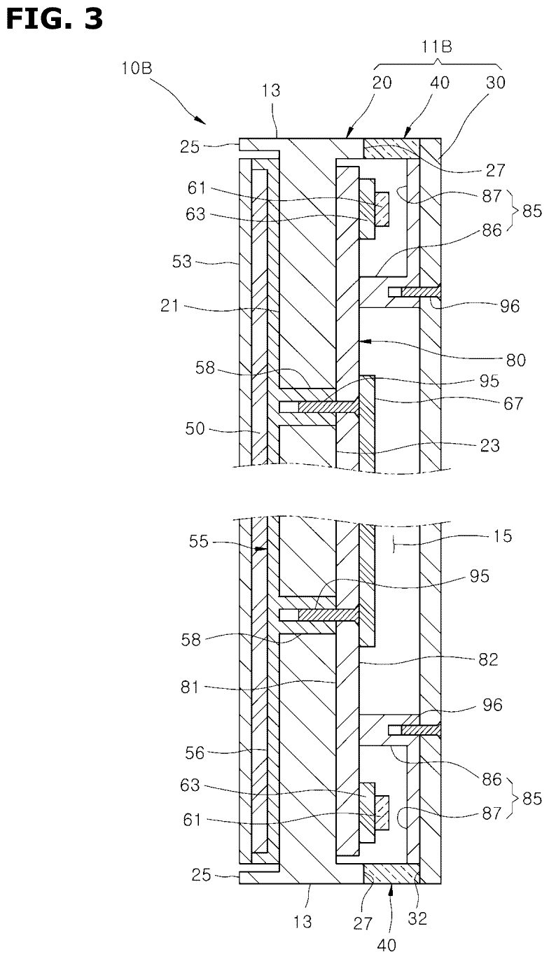

FIG. 3 is a cross-sectional view of a side light-emitting display device according to a second embodiment of the present disclosure, and corresponds to FIG. 2 illustrating the side light-emitting display device according to the first embodiment of the present disclosure, which has been described with reference to FIGS. 1 and 2.

Referring to FIG. 3, a side light-emitting display device 10B according to the second embodiment of the present disclosure may include a case 11B, a front display panel 50, a plurality of color LED packages 61, that is, a side light source, side light source circuit boards 63, a main circuit board 67, a heat dissipation panel 80, an internal housing 55, protection glass 53, and a light reflector 85. The case 11B may include a frame 20, a rear cover 30, and a light diffusion plate 40.

The frame 20, the rear cover 30, the front display panel 50, the plurality of color LED packages 61, the side light source circuit boards 63, the main circuit board 67, the internal housing 55, and the protection glass 53 are the same as the components having the same names, which are included in the side light-emitting display device 10A according to the first embodiment of the present disclosure, and are indicated by the same reference numerals as those of the components of the side light-emitting display device 10A and thus a redundant description thereof are omitted.

The heat dissipation panel 80 may discharge heat from the side light source circuit boards 63 and the main circuit board 67 by coming into contact with and supporting the side light source circuit boards 63 and the main circuit board 67. The heat dissipation panel 80 may be supported against a rear part 23 of the frame 20. For proper heat dissipation performance, the securing of strength, and a cost reduction, the heat dissipation panel 70 may be formed of a metal material including aluminum, for example, an aluminum alloy or pure aluminum.

The heat dissipation panel 80 included in the side light-emitting display device 10B according to the second embodiment of the present disclosure may not include a portion corresponding to the light blocking rib 75 that is included in the heat dissipation panel 70 of the side light-emitting display device 10A according to the first embodiment of the present disclosure.

A plurality of boss portions 58 included in the internal housing 55 extends toward the heat dissipation panel 80 through the frame 20. The heat dissipation panel 80 and the plurality of boss portions 58 may be mutually coupled and fixed by a plurality of fastening screws 95.

The light diffusion plate 40 included in the case 1B enables light that is projected from the side light source, that is, the plurality of color LED packages 61, to be projected from a side surface 13 of the case 11B to the outside while diffusing the light. The light diffusion plate 40 may be installed between the frame 20 and the rear cover 30 so that a gap 32 of the side surface 13 of the case 11B is closed.

A so-called hotspot phenomenon does not occur or can be reduced in the light L that is emitted from the side surface 13 of the case 11B because the light diffusion plate 40 diffuses the light L that is projected from the color LED packages 61 and passes through the gap 32.

The light diffusion plate 40 included in the side light-emitting display device 10B according to the second embodiment of the present disclosure may not include a portion corresponding to the reinforcement part 38 that is included in the light diffusion plate 35 of the side light-emitting display device 10A according to the first embodiment of the present disclosure.

The light reflector 85 may reflect light that is projected from the plurality of color LED packages 61, that is, the side light source, and that proceeds in a direction that becomes distant from the gap 32 so that the light proceeds toward the gap 32. The light reflector 85 may be installed in a case-internal space 15.

The light reflector 85 may include a first reflection part 86 and a second reflection part 87. The first reflection parts 86 may separate a central part of the case-internal space 15 in which the main circuit board 67 has been disposed and a surrounding part of the case-internal space 15 in which the plurality of LED packages 61 has been disposed.

Like the side light source circuit boards 63, the first reflection parts 86 may extend in a direction in which the plurality of color LED packages 61 has been arranged. The side light source may be disposed between the first reflection part 86 and the gap 32 close to the first reflection part 86.

The second reflection part 87 may be disposed behind the side light source between the first reflection part 86 and the gap 32 close to the first reflection part 86. The second reflection part 87 may be supported against a front surface of the rear cover 30 by being brought into contact therewith. The first reflection part 86 and the second reflection part 87 may be connected to form an angle at which the first reflection part 86 and the second reflection part 87 are approximately almost perpendicular to each other. The rear cover 30 and the first reflection parts 86 may be mutually coupled and fixed by fastening screws 96.

Brightness of the light L that is emitted through the gap 32 can be improved because the light L reflected by the light reflector 85 can be emitted to the side surface 13 of the case 11B through the gap 32. Furthermore, the overheating of the main circuit board 67 can be prevented because the light reflector 85 blocks the light L that is directed toward the central part of the case-internal space 15 without being directed toward the gap 32.

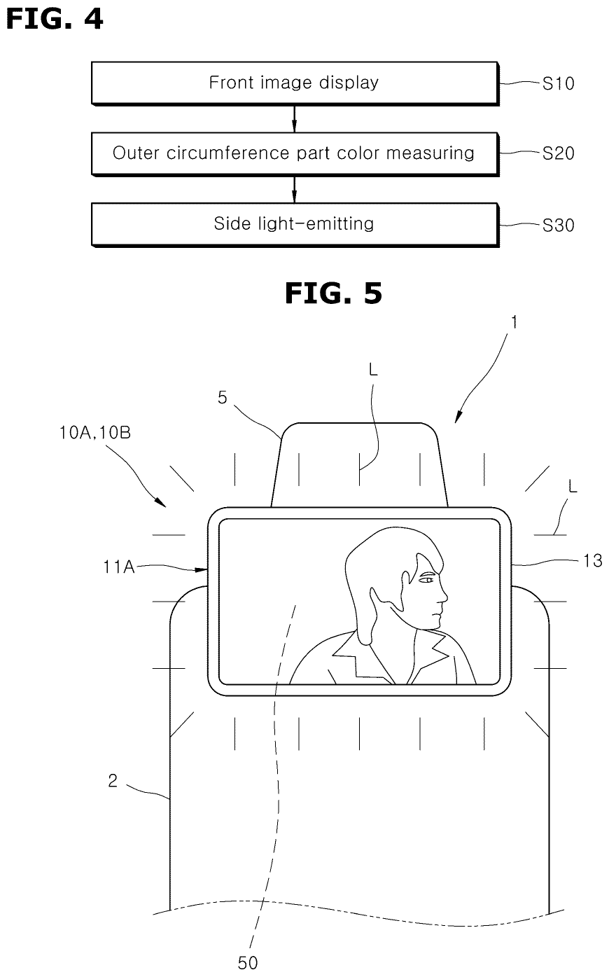

FIG. 4 is a flowchart illustrating an example of a method of using the side light-emitting display device according to an embodiment of the present disclosure. Referring to FIGS. 1 to 4, the method of using the side light-emitting display device 10A or 10B may include a front image display step S10, an outer circumference part color measuring step S20, and a side light-emitting step S30. The front image display step S10, the outer circumference part color measuring step S20, and the side light-emitting step S30 may be automatically performed by a control circuit of the main circuit board 67, for example.

The front image display step S10 is a step of displaying an image on the front display panel 50 when a user watches image content through the side light-emitting display device 10A or 10B. The outer circumference part color measuring step S20 is a step of measuring a color of the outer circumference part of the front display panel 50 per pixel of the outer circumference part.

The side light-emitting step S30 is a step of turning on the plurality of color LED packages 61, that is, the side light source, so that the plurality of color LED packages 61 emits the light L having a color corresponding to a color of the outer circumference part of the front display panel 50. For example, the color corresponding to the color of the outer circumference part of the front display panel 50 may be the same color or may be a color that is converted according to a predetermined rule.

In this case, the color of one pixel of the outer circumference part of the front display panel 50 and the color of the color LED package 61 closest to the pixel may correspond to each other. A predetermined representative color of a plurality of pixels and a color of the color LED package 61 closest to the plurality of pixels may correspond to each other.

Although not illustrated in FIG. 4, a step of selecting, by a user of the side light-emitting display device 10A or 10B, whether to execute side lighting using the side light source may be further included between the front image display step S10 and the outer circumference part color measuring step S20.

Unlike in the method illustrated in FIG. 4, the side light-emitting display device 10A or 10B may use the side light source as side lighting by turning on the side light source although an image is not displayed on the front display panel 50. In this case, the side light-emitting display device 10A or 10B may be preset so that the light L having different colors are emitted by the side light source depending on modes for music listening, meditation, and reading, for example.

FIG. 5 is a front view illustrating the state in which the side light-emitting display device of FIGS. 1 to 3 has been installed within a vehicle. As illustrated in FIG. 5, the side light-emitting display device 10A or 10B may be detachably installed in any one of a backrest part 2 and head rest part 5 of a seat 1 that is disposed in a seat in front of a passenger in means of transportation, for example, a vehicle or an airplane or may be detachably installed between the backrest part 2 and the head rest part 5.

When a passenger watches image content by using the side light-emitting display device 10A or 10B according to an embodiment of the present disclosure, the passenger may have an effect in that a screen of the front display panel 50 looks bigger and a visual stimulus, such as a surrounding image that hinders the immersion of the image content, may not appear on the screen because the light L having a color corresponding to a color of the outer circumference part of the front display panel 50 is emitted from the side surface 13 of the case 11A or 11B to surroundings thereof.

Accordingly, concentration and a feeling of immersion of the passenger who views the side light-emitting display device 10A or 10B are improved. Accordingly, work efficiency can be improved if the passenger performs a work, and the passenger can have an interesting and comfortable leisure time if the passenger enjoys leisure within the means of transportation.

Furthermore, if a user of the side light-emitting display device 10A or 10B according to an embodiment of the present disclosure turns on only the side light source without turning on the front display panel 50, the user can have a sense of psychological stability and take a calm rest because the side light source may function as indirect lighting or major lighting.

The present disclosure has been described above with reference to the embodiments illustrated in the accompanying drawings, but the embodiments are merely illustrative. A person having ordinary knowledge in the art to which the present disclosure pertains will understand that various modifications and other equivalent embodiments are possible from the embodiments. Accordingly, the true technical range of protection of the present disclosure should be determined by the claims below.

What is claimed is:

1. A side light-emitting display device comprising:
a case;
a front display panel configured to display an image to a front of the case; and
one or more side light sources spaced apart from the front display panel and configured to emit light to a side surface of the case.

2. The side light-emitting display device of claim 1, wherein each of the side light sources comprises one or more color LED packages configured to emit light having a plurality of different colors.

3. The side light-emitting display device of claim 2, wherein each of the color LED packages is arranged within an internal space of the case along the side surface of the case.

4. The side light-emitting display device of claim 1, wherein the case comprises a light diffusion plate configured to enable the light projected from at least one of the side light sources to be projected from the side surface of the case to an outside of the case while diffusing the light.

5. The side light-emitting display device of claim 1, wherein:
the case comprises a frame disposed behind the front display panel and a rear cover disposed behind the frame, and
an internal space of the case in which the side light source is disposed is located between the frame and the rear cover.

6. The side light-emitting display device of claim 5, wherein a gap from which the light projected from the side light source is emitted is formed between an outer edge of the frame and an outer edge of the rear cover.

7. The side light-emitting display device of claim 6, wherein a side light source circuit board on which the side light source is mounted, and a heat dissipation panel configured to support the side light source circuit board, are disposed in the internal space of the case.

8. The side light-emitting display device of claim 7, wherein the heat dissipation panel comprises a light blocking rib configured to block the light projected from the side light source so that the light does not proceed in a direction opposite that of the gap.

9. The side light-emitting display device of claim 7, further comprising boss portions configured to fix and support the front display panel and to extend toward the heat dissipation panel through the frame.

10. The side light-emitting display device of claim 9, wherein the heat dissipation panel and the boss portions are fastened together by fastening screws.

11. The side light-emitting display device of claim 7, wherein the heat dissipation panel is formed of a metal comprising aluminum.

12. The side light-emitting display device of claim 6, further comprising a light reflector installed in the internal space of the case and configured to reflect the light projected from the side light source and proceeding apart from the gap so that the light proceeds toward the gap.

13. The side light-emitting display device of claim 1, wherein the one or more light sources are located within the case.
